(19) United States
(12) Patent Application Publication
(10) Pub. No.: US 2019/0071766 A1
(43) Pub. Date: Mar. 7, 2019

(54) GOLD COATED COPPER FILM AND METHOD FOR MANUFACTURING SAME

(71) Applicants: Hyeuk-Jeon KWEON, Daegu (KR); Sang-Mok LEE, Daegu (KR)

(72) Inventors: Hyeuk-Jeon KWEON, Daegu (KR); Sang-Mok LEE, Daegu (KR)

(73) Assignees: JIN YOUNG R&S CO., LTD, Daegu (KR); JIN YOUNG R&S CO., LTD, Daegu (KR)

(21) Appl. No.: 15/739,971

(22) PCT Filed: Aug. 1, 2017
(86) PCT No.: PCT/KR2017/008309

§ 371 Date: Dec. 26, 2017

(30) Foreign Application Priority Data
Apr. 28, 2017 (KR) 10-2017-0054984

(51) Int. Cl. C23C 14/16; B23K 1/19; H05K 1/09; B32B 15/20

(52) U.S. Cl. CPC C23C 14/16; B32B 15/20; H05K 1/09; B23K 1/19

(57) ABSTRACT

This invention relates to a gold coated copper layer, comprising: a metal layer formed of a copper-containing material; a metal protective layer positioned on the metal layer and formed of brass, manganese brass, phosphor bronze, delta metal, naval brass, aluminum-brass alloy, copper-tin alloy, bronze, or copper-lead alloy; and a gold layer on the metal protective layer.

### TECHNICAL FIELD

The present invention relates to a gold coated copper film and a method for manufacturing the same.

### BACKGROUND ART

Generally, metal surface treatment techniques such as plating, thermal evaporation, or sputtering have been implemented to improve corrosion resistance and abrasion resistance of metals as well as color and luster of metal surfaces.

In specifically, gold among surface treatment materials of metals enhances value product and has excellent thermal and elastic properties to have been widely used as terminals and wirings of devices in the field of electronic and semiconductor devices.

Accordingly, gold plating methods have been widely employed in household items as well as various kinds of industries such as electronic and semiconductor devices.

In the meanwhile, surface treatment processes are performed finally in manufacturing Printed Circuit Board (PCB).

These surface treatment processes are very important because they are capable of preventing surface oxidation of solder pads until a final soldering process is completed.

Typical examples of surface treatment techniques are Hot Air Solder Leveling (HASL), Elecrtoless gold plating, Organic Solder ability Preservative (OSP) called as Pre-flux, Electroless tin plating, Electroless silver plating, and Palladium plating.

Gold plating is generally a method of depositing gold onto the surface of another metal, most often copper. In this case, nickel as barrier layer is deposited on copper before depositing gold onto copper to prevent gold from being permeated into copper.

However, there is a problem that the oxidation of nickel after a soldering process causes nickel to be peeled.

And, it is impossible to detect peeling of nickel until a soldering process is completed, thereby increasing defect rate of products.

### SUMMARY OF THE INVENTION

It is therefore an object of the present invention to provide a gold coated copper film for preventing peeling phenomenon of layers stacked on metals to reduce defect rate.

Pursuant to embodiments of the present invention provides a gold coated copper film comprising: a metal layer formed of a copper-containing material; a metal protective layer positioned on the metal layer and formed of brass, manganese brass, phosphor bronze, delta metal, naval brass, aluminum-brass alloy, copper-tin alloy, bronze, or copper-lead alloy; and a gold layer on the metal protective layer.

Pursuant to embodiments of the present invention, the metal layer is formed of a rolled copper foil, an electrolytic copper foil, or a copper foil for battery.

Pursuant to embodiments of the present invention, the metal layer has a thickness ranging from 10 μm to 100 μm, the metal protective layer has a thickness ranging from 200 Å to 1000 Å, and the gold layer has a thickness ranging from 200 Å to 1000 Å.

Pursuant to embodiments of the present invention, a method for manufacturing a gold coated copper film, comprising: forming a metal protective layer through a roll-to-roll sputtering on a metal layer formed of a copper-containing material; and forming a gold layer on the metal protective layer through a roll-to-roll sputtering. In this case, the metal protective layer is formed of brass, manganese brass, phosphor bronze, delta metal, naval brass, aluminum-brass alloy, copper-tin alloy, bronze, or copper-lead alloy.

It is another object of the present invention to, the metal layer is formed of a rolled copper foil, an electrolytic copper foil, or a copper foil for battery.

Pursuant to embodiments of the present invention, forming a connecting part for connecting terminals of components and the gold layer on the gold layer through a soldering process on the gold layer is further included.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 shows a cross-sectional view of a gold coated copper film according to the present invention;

FIGS. 2 and 3 show cross-sectional views of a method for manufacturing a gold coated copper film according to an embodiment of the present invention; and

FIGS. 4 and 5 show an exemplary soldering process of a gold coated copper film and components with terminals.

### DETAILED DESCRIPTION

Hereinafter, the present invention will be described in detail with reference to the drawings. In describing the present invention, detailed descriptions related to publicly known functions or configurations will be omitted in order not to obscure the gist of the present invention.

As used herein, the phrase “accessed” or “connected” refers that one element is directly accessed or connected to other element, or other element is formed therebetween. On the other hand, as used herein, the phrase “directly accessed” or “directly connected” refers that there is no element therebetween.

In advance, a gold coated copper film will be described in more detail with reference to FIG. 1.

As shown in FIG. 1, the gold coated copper film 100 according to an embodiment of the present invention comprise a metal layer 110, a first and second metal protective layers 121 and 122, and a first and second gold layers 131 and 132. The first and second metal protective layers 121 and 122 are positioned on upper and lower surfaces of the metal layer 110, respectively. The first and second gold layers 131 and 132 are positioned on upper and lower surfaces of the first and second metal protective layers 121 and 122, respectively.

A wiring may be located on at least one of the first and second gold layers 131 and 132.

The metal layer 110 according to the present invention is a copper foil formed of a copper-containing material, and more concretely, may be a rolled copper foil, an electrolytic copper foil, or a copper foil for battery.

The metal layer 110 has a thickness ranging from 10 μm to 100 μm.

The first and second metal protective layers 121 and 122 positioned on upper and lower surfaces of the metal layer 110 have the same thickness. For instance, they

The first and second metal protective layers 121 and 122 may be formed of brass, manganese brass, phosphor bronze, delta metal, naval brass, aluminum-brass alloy, copper-tin alloy, bronze, or copper-lead alloy.

The first and second gold layers 131 and 132 positioned on upper and lower surfaces of the first and second metal protective layers 121 and 122, respectively and formed of gold (Au) have a thickness ranging from 200 Å to 1000 Å.

According to the present invention, after stacking the metal protective layers 121 and 122 formed of a copper alloy on a metal layer instead of directly stacking gold (Au) on a metal layer formed of copper, a sputtering process is performed with respect to gold. As a result, the gold is prevented from being permeated into the metal layer, the adhesion between the metal layer 110 and the gold is enhanced, and the luster of formed gold layers 131 and 132 are improved.

Furthermore, by employing the sputtering process instead of the plating process and oxidation through the soldering process, the copper alloy is used as the metal protective layer instead of the nickel layer for causing the plated gold to be peeled, thereby preventing the gold layer from being peeled after the soldering process.

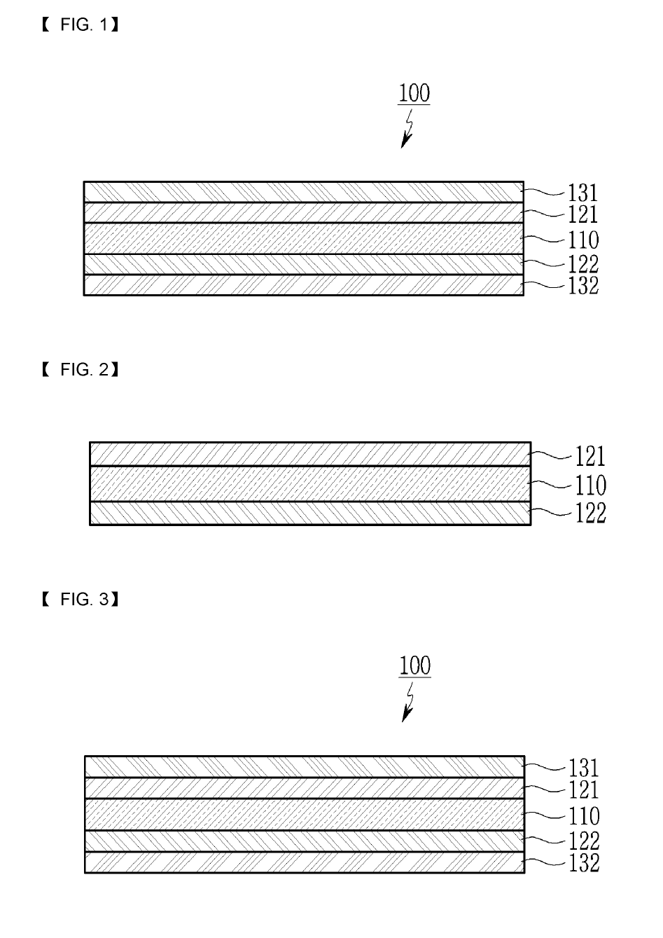

A method for manufacturing the above-mentioned gold coated copper film 100 will be explained with reference to FIGS. 2 and 3.

In some embodiments of the present invention, each of layers are sequentially formed using one chamber in which compartments separated by partitions as many as the number of stacked layers in order to one gold coated copper film 100. Unlike this, each of the layers may be sequentially formed in different chambers.

The metal layer 110 being a base layer is moved to the corresponding compartment of a process chamber for stacking each of wanted layers.

In this case, the metal layer 110 may be formed of a rolled copper foil, an electrolytic copper foil, or a copper foil for battery.

In some embodiments of the present invention, each of the layers 110, 121, 122, 131, and 132 are formed through a roll-to-roll sputtering process.

At this time, the initial vacuum of the process chamber is maintained ranging from 1×10⁻⁶ torr to 9×10⁻⁶ torr.

Under this initial vacuum, water of the metal layer 110 is removed. To reach a wanted vacuum, a turbo pump, a dispenser pump, or a cryo pump may be used.

Like this, if the initial vacuum of the process chamber is adjusted to a wanted level, atmosphere gas, that is, inert gas (e.g., argon gas) is inlet to the process chamber for forming plasma for the sputtering process. As a result, the initial vacuum of the process chamber is adjusted ranging from 1×10⁻³ torr to 9×10⁻³ torr, and more preferably, ranging from 1×10⁻³ torr to 5×10⁻³, so that the initial vacuum of the process chamber is adjusted from an initial state to a tasking state.

In this case, the injection amount of argon gas (Ar) may be ranged from 100 sccm to 500 sccm.

If, the sputtering process is stably performed so that wanted layers are stably stacked. If the injection amount of argon gas is less than an upper value, when plasma is formed by increasing the number of generated ions, a stacking efficiency is not decreased in spite of collision of plasma and ions.

Under this atmosphere of the process chamber, if power supply from a DC power generator or a DC pulse power generator is applied, an injected sputtering gas (Ar gas) is collided with electrons discharged from the anode (e.g., from target material) to excited to be Ar⁺. The excited argon gas (Ar⁺) is moved to the anode in which the target material is located to be collided with the target material. These collisions create plasma to trigger stacking on the metal layer positioned at the cathode so that the first and second metal protective layers 121 and 122 formed of the target materials are stacked on the upper and lower surfaces of the metal layer 110, respectively (See FIG. 2).

In order to form the first and second protective layers 121 and 122 on front surface (upper surface) and rear surface (lower surface) through the sputtering process, respectively, after forming the first metal protective layer 121 or the second metal protective layer 122 on the front and rear surfaces of the metal layer 110 in advance, the first metal protective layer 121 or the second metal protective layer 122 is formed on surfaces (front surface or rear surface) of the rest of the metal layer 110 under the same atmosphere of the process chamber.

In some embodiments of the present invention, the target material for the first and second metal protective layers 121 and 122 is formed of copper alloy, for example, brass, manganese brass, phosphor bronze, delta metal, naval brass, aluminum-brass alloy, copper-tin alloy, bronze, or copper-lead alloy (e.g., bronze).

Like this, if a copper foil formed by stacking the first and second metal protective layers 121 and 122 is formed on the metal layer 110, the copper foil is moved to a compartment for stacking the first and second gold layers 131 and 132.

If the equivalent amount of argon gas being atmosphere gas is injected into a corresponding compartment in which gold (Au) being a target material for the first and second gold layers 131 and 132 and power supply is applied, the first and second gold layers 131 and 132 are formed on the first and second metal protective layers 121 and 122 through a sputtering process by argon gas (Ar⁺) (See FIG. 3). In this case, the formation sequence of the first and second gold layers 131 and 132 is changed as occasion demands.

The injection amount of argon gas (Ar) for the first and second gold layers 131 and 132 may be ranged from 100 sccm to 500 sccm.

As mentioned above, the first and second metal protective layers 121 and 122 are formed not by a plating process but by a sputtering process. The sputtering process is performed without foreign matters under vacuum condition, and the plating process is performed by injecting foreign matters.

For this reason, several problems caused by foreign matters such that at least one of the first and second metal protective layers 121 and 122 is oxidized or the gold layers 131 and 132 are peeled can be prevented or reduced.

In addition, cracks or oxidation due to foreign matters during a soldering process for forming wirings can be prevented to reduce defect rate of wiring contact.

Additionally, in some embodiments of the present invention, copper alloy having heat resistance is employed as the first and second metal protective layers 121 and 122 during high temperature process for a soldering process instead of nickel that occurs thermo-oxidation phenomenon. As a result, oxidation due to high temperature process performed during a soldering process can be reduced or prevented. As described above, foreign matters can be prevented in forming the first and second metal protective layers 121 and 122, thereby preventing cracks or oxidation due to foreign matters during the soldering process.

Since the compactness and smoothness of a film formed through is higher than, the compactness and smoothness of the first and second metal protective layers 121 and 122 a sputtering process is higher than those of them formed by a plating process.

Accordingly, it is difficult for oxygen and foreign matters to permeate into the first and second metal protective layers 121 and 122 so that oxidation and peeling thereof becomes reduced.

Also, owing to the increment of the compactness and smoothness of the first and second metal protective layers 121 and 122, the adhesion of the gold layers 131 and 132 becomes enhanced to reduce use of gold although the gold layers 131 and 132 have a thinner thickness than before.

Furthermore, the luster is increased by copper alloy to improve aesthetic impression.

In some embodiments of the present invention, the amount of argon gas for being injected into a corresponding compartment for forming the metal protective layers 121 and 122 is the same or different from that for being injected into a corresponding compartment for forming the first and second gold layers 131 and 132.

In addition, the driving speed of the metal layer 110 for a roll-to-roll sputtering process may be from 1 to 10 m/min.

In this case, the driving speed of the metal layer 110 and electric power applied for forming plasma during a sputtering process, in other words, power supply of a DC power generator or a DC pulse power generator can be determined depending on a stacked thickness of each of the layers 121, 122, 131, and 132.

Like this, the gold coated copper film where the gold layers 131 and 132 having a wanted thickness on the metal layer 110 may be used as wirings located on a Printed Circuit Board (PCB) for mounting components.

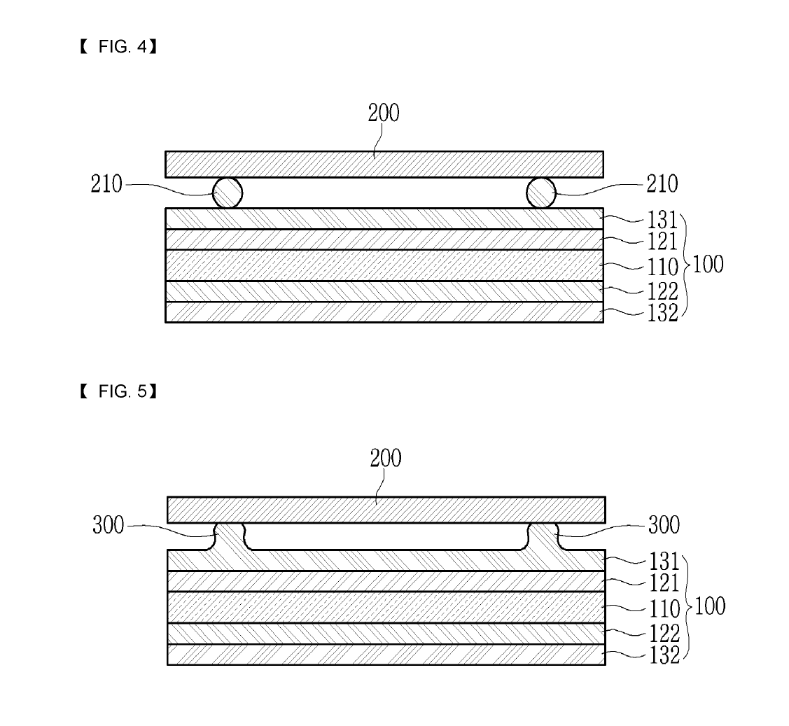

Next, an exemplary soldering process for connecting the PCB in which the gold coated copper film is used as wirings and components thereon will be described referring to FIGS. 4 and 5.

In some embodiments of the present invention, the gold coated copper film 100 and the components 200 of the PCB including solder balls as terminals for electrically connecting components 200 of the PCB and gold coated copper film 100 located thereunder are described, but is not limited to the above described embodiment.

As shown in FIG. 4, in order to electrically and physically connect the gold coated film 100 and the component 200 having solder ball 210, terminals, that is, the component 200 having the solder balls 210 is located on a wanted gold coated copper film 100 using a flip chip process or a pick-and-place process.

Next, to fix the component 200 positioned on the gold coated copper film 100, heat treatment is performed with respect to the PCB in which the gold coated copper film 100 is located using an oven and the like. At this time, heat treatment temperature is ranged from 100° C. to 300° C., and heat treatment time is ranged from 1 minute to 3 minutes.

Through this heat treatment, gold (Au) contained in the gold coated copper film 100 is melted to electrically and physically connect the gold coated copper film 100 and the solder balls 210 of the components thereon, thereby forming a connecting part 300 for connecting the solder balls 210 being terminals of components and the gold layer 131 or 132 of the gold coated copper film 100.

As mentioned earlier, the terminals of the components are formed of the solder balls as an example of the invention, but not limited to the embodiments set forth herein and various modifications to the preferred embodiments will be readily apparent to those skilled in the art and various soldering processes herein may be applied to other embodiments.

In some embodiments of the present invention, the metal protective layers 121 and 122 and the gold layers 131 and 132 are located on front and rear surfaces of the metal layer 110, respectively in the gold coated copper film 100, but not limited to the embodiments set forth herein. Accordingly, the metal protective layers 121 and 122 and the gold layers 131 and 132 are located on one of front and rear surfaces of the metal layer 110, respectively in the gold coated copper film 100.

According to the present invention, after stacking the metal protective layers formed of the copper alloy on a metal layer instead of directly stacking gold on the metal layer formed of copper, a sputtering process is performed with respect to gold. As a result, the gold is prevented from being permeated into the metal layer, the adhesion between the metal layer and the gold is enhanced, and the luster of the formed gold layers are improved.

In addition, before forming the first and second metal protective layers 121 and 122, a surface modification is performed with respect to the metal layer 110 using a DC bombard process thereby enhancing stacking efficiency of the first and second metal protective layers 121 and 122 formed on the metal layer 110.

Also, by employing the sputtering process instead of the plating process and oxidation through the soldering process, the copper alloy is used as the metal protective layer instead of the nickel layer for causing the plated gold to be peeled, thereby preventing the gold layer from being peeled after the soldering process.

All such changes, modifications, variations and other uses and applications which do not depart from the spirit and scope of the invention are deemed to be covered by the invention which is limited only by the claims which follow.

What is claimed is:

1. A gold coated copper film comprising:
a metal layer formed of a copper-containing material;
a metal protective layer positioned on the metal layer and formed of brass, manganese brass, phosphor bronze, delta metal, naval brass, aluminum-brass alloy, copper-tin alloy, bronze, or copper-lead alloy; and
a gold layer on the metal protective layer.

2. The gold coated copper film of claim 1, wherein the metal layer is formed of a rolled copper foil, an electrolytic copper foil, or a copper foil for battery.

3. The gold coated copper film of claim 1, wherein the metal layer has a thickness ranging from 10 μm to 100 μm, the metal protective layer has a thickness ranging from 200 Å to 1000 Å, and the gold layer has a thickness ranging from 200 Å to 1000 Å.

4. A method for manufacturing a gold coated copper film, comprising:
forming a metal protective layer through a roll-to-roll sputtering on a metal layer formed of a copper-containing material; and
forming a gold layer on the metal protective layer through a roll-to-roll sputtering, wherein the metal protective layer is formed of brass, manganese brass, phosphor bronze, delta metal, naval brass, aluminum-brass alloy, copper-tin alloy, bronze, or copper-lead alloy.

5. The method of claim 4, wherein the metal layer is formed of a rolled copper foil, an electrolytic copper foil, or a copper foil for battery.

6. The method of claim 4, further comprising forming a connecting part for connecting terminals of components and the gold layer on the gold layer through a soldering process on the gold layer.
